(19) United States
(12) Patent Application Publication
(10) Pub. No.: US 2005/0098022 A1
(43) Pub. Date: May 12, 2005

(54) Hand-held music-creation device

(76) Inventors: Eric Shank, San Francisco, CA (US); Catherine Sun, San Francisco, CA (US); Joseph Forest, Amesbury, MA (US)

Correspondence Address: FROST BROWN TODD, LLC, 2200 PNC CENTER, 201 E. FIFTH STREET, CINCINNATI, OH, 45202, US

(21) Appl. No.: 10/983,533

(22) Filed: Nov. 8, 2004

Related U.S. Application Data
(60) Provisional application No. 60/518,217, filed on Nov. 7, 2003.

(51) Int. Cl. G11C 5/00; G10H 7/00

(52) U.S. Cl. 84/612

(57) ABSTRACT

A hand-held music-creation device has a plurality of stored samples of sound. The device has an interface comprising a grid, where the rows represent channels in which samples may be selected and the columns represent loop measures. The device allows the user to select which samples are to be played in a given loop measure. A loop is created by assigning samples to available loop measures. The user may hear the resulting composition, comprising a loop repeating indefinitely. Each device may be connected to at least one other device to form a system. The system allows the creation of a longer loop and/or allows an increase in sample selection for each loop measure in the loop.

### PRIORITY

This application claims priority from the disclosure of U.S. Provisional Patent Application Ser. No. 60/518,217, entitled “Hand-Held Music-Creation Device,” filed Nov. 7, 2003.

### TECHNICAL FIELD

The present invention relates generally to music-creation devices, and is particularly directed to hand-held programmable devices which produce music as single units and/or as a system of connected units.

### BACKGROUND OF THE INVENTION

The many benefits of getting children involved with music early on in their lives are well known. Many of these benefits may be achieved by allowing children to create electronic or similar music compositions. While software and hardware tools are available to create songs by digitally manipulating music samples, children have been left somewhat behind in the field of loop-based music creation. Most existing loop-based music-creation products are targeted at adults and lack typical attributes of a child's toy.

Existing loop-based music-creation products include large pieces of equipment having dozens of complicated controllers. These devices are typically created for adults, yet such devices have interfaces so complex that many adults, let alone children, would be unable to easily manipulate them to create coherent musical compositions. In addition to being too complex for a child to use, such equipment is typically too expensive for purchase as a child's toy.

The art also includes software-based music-creation products that use samples and loops. However, such existing software also includes interfaces and features too complex for a child to use effectively. While some children may be able to use certain software-based electronic music-creation programs, such programs lack the typical attributes of a toy such as portability and aesthetics. In addition, not all children have access to software-based electronic music-creation programs for a variety of reasons.

Ultimately, the field of music creation lacks an affordable, hand-held device that children may easily use to compose music from a set of samples.

### SUMMARY OF THE INVENTION

The present invention comprises a hand-held music-creation device that allows a user to easily compose a song by combining short sound files, also known as “samples.” The combination of samples creates a “loop,” which repeats indefinitely. The repeating loop creates a musical composition. As each individual device, or unit, may have its own speaker, the single hand-held unit may constitute a self-contained means of producing a composition whose attributes may be easily controlled via the simple user interface.

Each unit may have a plurality of sound samples stored or otherwise accessible by a user. The device may have an interface comprising a grid, where the rows may represent channels and the columns may represent intervals of time, or loop measures. The device allows the user to select the samples that are to be played in a channel during a given loop measure. When samples are assigned to all available loop measures in the channels, a loop is created. The resulting composition, comprised of such a loop repeating indefinitely, may be heard by the user.

The present invention further comprises a system where said units are connected to produce musical effects that may not be accomplished with a single unit alone. Each unit may be capable of being connected to at least one other unit to form a system. The system may allow the creation of a longer loop and/or allow an increase in sample selection for each loop measure in the loop. Should the samples in one unit in the system play at a tempo that is dissimilar to the tempo of samples in another unit in the system, the tempo of the overall composition is capable of being made uniform. Other characteristics of the samples and/or loop and/or composition may be altered by the user.

These and other objects and advantages of the present invention shall be made apparent from the accompanying drawings and the description thereof.

### BRIEF DESCRIPTION OF THE FIGURES

The accompanying drawings, which are incorporated in and constitute a part of this specification, illustrate possible embodiments of the invention, and, together with the general description of the invention given above, and the detailed description of the possible embodiments given below, serve to explain the principles of the present invention. While the specification concludes with claims that particularly point out and distinctly claim the invention, it is believed the present invention will be better understood from the following description taken in conjunction with the accompanying drawings, in which like reference numerals identify the same elements. The drawing and detailed description which follow are intended to be merely illustrative and are not intended to limit the scope of the invention as set forth in the appended claims

FIG. 1 depicts a perspective view of an exemplary hand-held music creation device.

FIG. 2 depicts a perspective view of the hand-held music creation device of FIG. 1.

FIG. 3 depicts a schematic diagram of a control circuit for the hand-held music creation device of FIG. 1.

FIG. 4 depicts a system of hand-held music creation devices of FIG. 1.

### DETAILED DESCRIPTION OF EMBODIMENTS OF THE INVENTION

The following description should not be used to limit the scope of the present invention. Other examples, features, aspects, embodiments, and advantages of the invention will become apparent to those skilled in the art from the following description, which includes by way of illustration, one of the best modes contemplated for carrying out the invention. As will be realized, the invention is capable of other different and obvious aspects, all without departing from the invention. Accordingly, the drawings and descriptions should be regarded as illustrative in nature and not restrictive.

One embodiment of the present invention comprises a hand-held music-creation device, or unit 2, that allows a user to easily compose a musical composition by combining samples that are accessible by or through the unit 2. As used herein, the term “sample” shall be understood to include a sound or collection of sounds stored in any suitable form. By way of example only, the form may be digital. A sample may also be understood as the absence of sound (e.g., a moment of silence). The sound or sounds comprising a sample will preferably have at least one pitch, as that term is understood in the art. By way of example only, the samples may be musical in nature, such that each sample comprises a melodic and/or rhythmic motif or riff. Accordingly, to the extent that each sample has a discernable rhythm, each sample may have a tempo, as that term is understood in the art. The duration of each sample may be any length of time. By way of example only, each sample may be one, two, four, or eight seconds in length. In one embodiment, each unit 2 includes a plurality of samples stored within the unit 2 in digital form.

It will also be appreciated that samples may be accessible by a unit 2 without the samples being stored within the unit 2. By way of example only, a unit may be operable to access samples stored in a location outside the unit 2. Such samples may be communicated to or through the unit 2 through a wire or wirelessly. Thus, the unit 2 may include a port for receiving remotely-communicated samples, or may include a receiver for receiving samples that are wirelessly communicated from a remote location. In addition, where a unit 2 is configured to store samples, it will be appreciated that the unit 2 may be configured to receive updates to samples stored. In other words, the unit 2 may receive additional samples from a remote location via wire or wirelessly, or the unit 2 may “dump” one or more samples stored within the unit 2. Thus, the selection of samples within a unit 2 or otherwise accessible by the unit 2 need not be fixed.

While the embodiments disclosed herein are operated electronically, such should not be read as a limitation of the invention, as electronic operation is a mere preferred embodiment. As will be appreciated by those in the art, any other suitable form of operation may be used, such as fiber optics by way of example only.

Samples may be aggregated by a unit 2 to form repeating loops, resulting in a musical composition. As used herein, the term “loop” shall be understood to include one or more samples. Thus, a loop may be understood to constitute a musical phrase that may be made to repeat indefinitely. A loop is typically comprised of loop measures.

The phrase “loop measure,” as used herein, shall be understood to include all meaning ascribed to the term “measure” by those of ordinary skill in the art. This meaning includes an interval, or block, of time. However, the phrase “loop measure,” as used herein, shall not be read to be exclusively limited to the common understanding of the term “measure” by those of ordinary skill in the art as a “bar,” or a metric unit between two bars on a musical staff, or a division of notated music according to the number of beats or subdivisions of the beat as indicated by a time signature. Indeed, a “loop measure,” as that phrase is used herein, may comprise more than one “measure,” as that term is used to describe a metric unit between two bars on a musical staff. In one embodiment, a loop measure comprises two measures. Thus, in this embodiment, where the meter of the samples comprises four-four time, each loop measure comprises eight beats (e.g., two measures of four beats). Other suitable characteristics for loop measures will be apparent to those of ordinary skill in the art.

A loop measure may be any length of time such as, for example, two, three, four, or eight seconds long. In one embodiment, the duration of each loop measure equals the duration of each sample. However, it will be appreciated that any given sample may repeat one or more times within a loop measure (e.g., a four second sample repeating to fill an eight second loop measure). In one embodiment, a loop measure is eight seconds in length, however any other duration may be used. The number of loop measures in a loop is finite.

As used herein, the term “composition” shall be understood to include a repeating loop or repeating loops. As a composition is typically comprised of a loop or loops repeating indefinitely, the number of loop measures in a composition may be indefinite. Alternatively, the number of loop measures in a composition may be definite. The term “composition” shall also be construed as synonymous with the phrase “musical composition,” and shall be read to further include all meaning understood in the art as to the phrase “musical composition.”

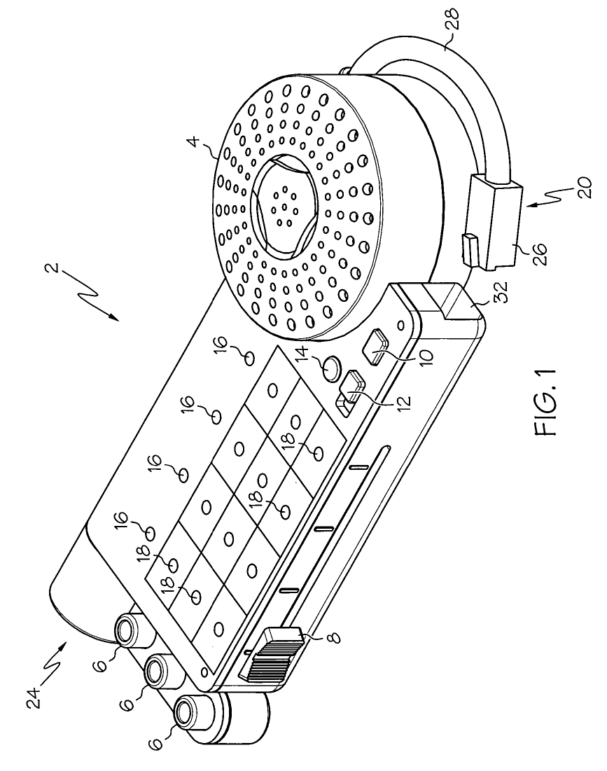

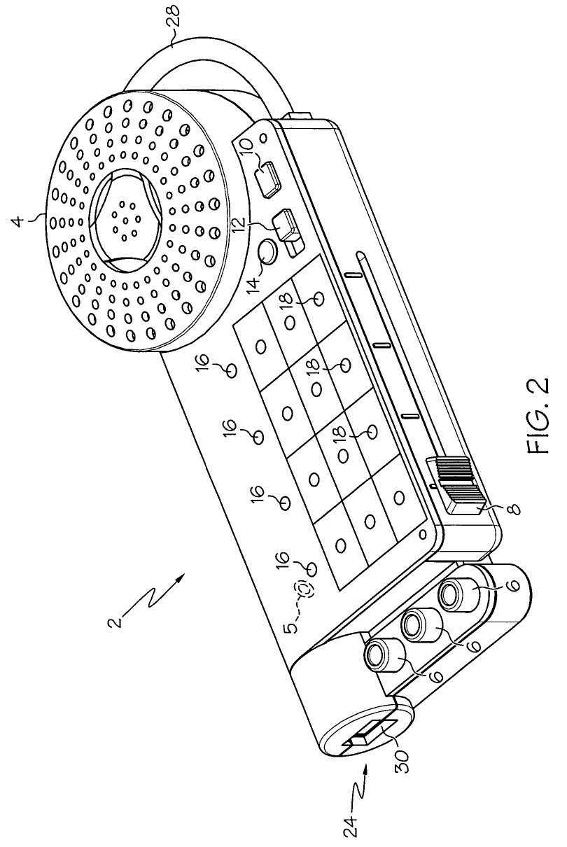

A merely exemplary embodiment of the present invention is shown in FIGS. 1 and 2. As each individual unit 2 may have its own communicator, the unit 2 may constitute a self-contained means of producing a composition whose attributes may be easily controlled via a simple user interface. As used herein, the term “communicator” shall be understood as including anything operable to communicate sound in any form. The communicated sound or sounds may be a function of stored sounds and processed signals. A communicator may be something that communicates sound directly, without the aid of any external device. Thus, a communicator could be, by way of example only, a speaker 4 as shown in FIGS. 1 and 2. Alternatively, a communicator may also include something that requires another device in order for the communicated sound to be heard by a user. Thus, a communicator could be, by way of example only, a headphone jack 5 or a USB port. Where a communicator is a headphone jack 5, a user may hear the communicated sound through headphones connected to the headphone jack 5. Where a communicator is a USB port, a user may hear the communicated sound with the aid of a computer or other device operable to receive and interpret signals communicated through a USB port. Other suitable communicators will be apparent to those of ordinary skill in the art. As shown in FIGS. 1 and 2, a unit 2 may have more than one communicator, such as a speaker 4 and a headphone jack 5, by way of example only.

Each unit 2 is preferably of a size such that it may be held in the hand of a user. Of course, a unit 2 may be of any suitable size.

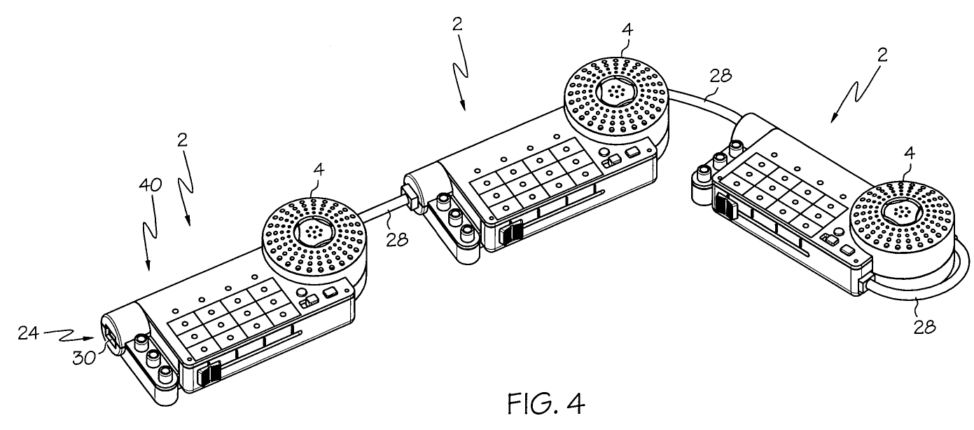

In another embodiment, a plurality of units 2 are connected to produce musical effects that may not be accomplished with a single unit 2. An example of a system of units is depicted in FIG. 4.

The user interface on each unit 2 is comprised of one or more sample selectors and one or more timing controllers. As used herein, the term “sample selector” shall be understood to include anything operable to select a sample from a collection of samples. A sample selector may be mechanically manipulated (or otherwise manipulated) by a user to select one or more samples. In addition, a sample selector may be operable to electronically or otherwise communicate a user's sample selection. Each sample selector may be understood as having one or more sample selection outputs. The sample selection output or outputs may be operable to electronically or otherwise communicate a selection of a sample or samples. Of course, the sample selection output need not communicate a sample, but may suffice to effect the selection thereof.

A sample selector could include, by way of example only, a button 6 as shown in FIGS. 1 and 2, a switch, a knob, or any suitable alternative. Where a unit 2 has samples stored within the unit 2, the one or more sample selectors on a unit 2 are operable to select one or more samples of sound that are stored in the unit 2. Alternatively, where one or more samples are stored outside the unit 2, a sample selector may be operable to select one or more samples from such remote samples.

The term “timing controller,” as used herein, shall be understood to include anything operable to temporarily select and isolate a loop measure such that samples may be selected for that loop measure. The editing of a loop measure includes the selection of samples to be played during that loop measure. For example, in the creation of a loop comprised of four loop measures, a timing controller may be used to facilitate the editing of one loop measure of the loop at a time. A timing controller may be mechanically manipulated (or otherwise manipulated) by a user to select a loop measure to be edited. In addition, a timing controller may be operable to electronically or otherwise communicate a user's loop measure selection. A timing controller may be understood as having one or more loop measure selection outputs. The timing controller output or outputs may be operable to electronically or otherwise communicate a selection of a loop measure to be edited. A timing controller could include, by way of example only, a slider 8 as shown in FIG. 1, a switch or switches, a knob, a timing controller button or buttons, or any suitable alternative.

The user interface may be based on a grid containing, for example, twelve positions to place samples or otherwise designate sample selections. In one merely exemplary embodiment, this grid comprises three horizontal rows that represent channels and four vertical columns that represent consecutive loop measures. Of course, these numbers could be changed depending on the complexity desired or other considerations. The term “channel,” as that term is used herein, shall be understood to include a plurality of loop measures wherein the samples of the channel are selectable by a sample selector. Thus, each channel may have its own respective sample selector. In other words, where there are a plurality of sample selectors, each sample selector may control a respective channel. Accordingly, the number of channels may equal or otherwise correspond to the number of sample selectors. In the present example, each sample selector button 6 corresponds to a respective channel. Thus, in this example, there are three channels.

Alternatively, if there is only one sample selector, that sample selector may be operable to select the samples to be played in a plurality of channels. This may be accomplished with a means for selecting a channel in which the samples are to be selected. Other suitable configurations and relationships between channels and sample selectors will be apparent to those of ordinary skill in the art.

“Channel” also includes all other meaning ascribed to that term by those of ordinary skill in the art.

The user interface on each unit 2 may include, by way of example only, three vertically-placed sample selector buttons 6 as sample selectors and a horizontally-moving slider 8 as a timing controller. Alternatively, the number of buttons 6 or other type of sample selector could be increased or decreased.

Following the above example where three buttons 6 were disclosed as sample selectors, the user may use each of the three buttons 6 to select samples. As each sample selector button 6 lies in its own row, and each row represents a channel, each button 6 will be operable to select the samples to be played in its corresponding channel. Each track will be aurally defined by the collection of samples selected by the user's manipulation of a channel's corresponding sample selector (when samples are, in fact, selected).

A ”track” is to be understood as including the aggregation of samples selected to be played in a single channel across the span of loop measures comprising the loop. Thus, each channel may have a respective track created therein. A loop will therefore be comprised of the tracks created in each channel. The tracks may play simultaneously to comprise the loop. Thus, for example, if there are three buttons 6 as sample selectors, then there are three corresponding channels. A track is created in each of the three channels; and therefore there may be up to three different tracks playing simultaneously at a given time.

Of course, the number of sample selector buttons 6 or button alternatives may be increased, which may increase the number of horizontal rows accordingly. An increase in the number of horizontal rows may increase the number of channels and corresponding tracks accordingly. Regardless of the number of sample selectors or type, each sample selector may have one or more outputs, such that the output or outputs are operable to electronically or otherwise communicate a selection of a sample of sound to a process controller such as, for example, a processor. A “process controller,” as that term is used herein, includes all meaning known to those skilled in the art as to the term “processor.” The term “process controller” further includes anything capable of processing user inputs, where the user inputs include, in part, indication of the selection of samples for each loop measure.

Following the above example where a slider 8 was disclosed as a timing controller and four columns were disclosed, when a user positions the slider 8 over one of the four columns, the user may choose which of the samples will play during the loop measure represented by the selected column. In other words, the slider 8 is operable to select and isolate a loop measure for the selection of samples to be played during the selected loop measure. In this way, the slider 8 may act as a timing controller, such that it will be operable to select a loop measure during which one or more selected samples will play. This, or any other type or types of timing controller or controllers may have one or more outputs. Such output or outputs may be operable to electronically or otherwise communicate a selection of a loop measure during which one or more selected samples of sound will play. A timing controller output may alternatively merely communicate the isolation of a selected loop measure to permit selection of samples for the selected loop measure. Other suitable timing controller configurations will be apparent to those of ordinary skill in the art.

In the present example, when the user moves the slider 8 off a column, the unit may “lock” the most recently selected sample(s) to play during the loop measure represented by the column. Thus, the unit 2 may be programmed by first positioning the slider 8 in the first column to permit selection of samples to be played during the first loop measure. When samples have been selected for the first loop measure, the slider 8 may then be positioned in the second column to permit selection of samples to be played during the second loop measure. This may be repeated until the user has selected the desired samples for all available loop measures.

The unit 2 may play the assigned samples for each loop measure, beginning with the first loop measure, represented by the first column on the left, then moving to the next loop measure represented by the adjacent column, and so on, until it plays the sample(s) assigned to the last loop measure represented by the last column on the right. After this cycle, the unit 2 may loop the music back to the first column on the left, such that the loop repeats itself, which can occur indefinitely. Again, any substitute alternative for a slider 8 may be used to select and isolate a loop measure for the selection of samples to be played therein. Additionally, more or less than four loop measures may be used, depending in part on the desired length of the loop that will repeat itself.

Following the above example where four loop measures, and hence, four columns representing the four loop measures, are disclosed, each column on the interface may have a loop measure LED 16 that will light when the unit 2 is playing the sample(s) assigned to the loop measure represented by the corresponding column. This may give the user visual feedback to show the part of the four-loop-measure loop from which the unit 2 is playing at any given time. Each loop measure LED 16 may be made to flash in synchronization with the tempo of the loop when the loop is at the loop measure corresponding to the loop measure LED 16. Any alternative to an LED may also be used.

Each unit 2 may be powered from a battery or any other suitable source. Each unit 2 may have a “power” or “on/off” button operable to turn the power from the power source to the unit 2 on and off. In one embodiment, the unit 2 is configured to automatically turn off after a certain period of inactivity. By way of example only, such a period may comprise three minutes.

Each unit 2 may also have a “play/stop” button 10 as shown in FIGS. 1 and 2. The “play/stop” button 10 may be operable to start and stop the playing of the composition by toggling the unit 2 between “play” mode and “stop” mode. Any suitable alternative may be used to achieve the same function. The “play/stop” button 10 may also be made operable to function as an “on/off” button. For example, the “play/stop” button 10 may serve the function of turning the unit 2 on or off when the “play/stop” button 10 is held down for a certain period of time. By way of example only, the “play/stop” button 10 may also be made operable to turn the unit 2 on or off when the “play/stop” button 10 is held down for three seconds. The duration required for holding the “play/stop” button 10 to turn the unit 2 on may differ from that required for turning the unit 2 off. Other functions may be performed by a “play/stop” button 10.

When the unit 2 is in “play” mode, the samples may play as selected and distributed among the loop measures, beginning at the first loop measure, which may be represented by a first column on the left, and continuing to the next loop measure, represented by the adjacent column on the right, and so on, until the last loop measure, represented by the right-most column, is completed, resulting in the indefinite repetition of a loop (i.e. the composition) that may be heard by a user. When the unit 2 is in “stop” mode, the composition may be stopped, and the user may edit the channels and/or loop measures individually.

A unit 2 may be placed in “edit” mode to permit a user to select samples to be played in each channel during each loop measure. The unit 2 may be placed in “edit” mode by any suitable means, such as manipulation of an “edit” button, by way of example only. In one embodiment, the unit 2 is deemed to be in “edit” mode when the unit 2 is “on” (e.g., consuming power from the power source), yet the unit 2 is not in “play” mode.

The user interface may include edit LED's, each corresponding to a loop measure. An edit LED may be made to light in correspondence to a loop measure selected by the slider 8, or whatever form of timing controller is employed. The lighting of an edit LED, and the corresponding placement of the slider 8 or other form of timing controller, may indicate that the selection of samples will only take place in the selected loop measure. Once a loop measure is selected during “edit” mode, a user may manipulate any of the sample selector buttons 6 as shown in FIGS. 1 and 2, or whatever types of sample selectors are employed, to select the sample to be played in the sample selector's corresponding channel during the selected loop measure. Any suitable alternative to edit LED's may be used, or they may be eliminated altogether.

In one embodiment, the loop measure LED's 16 act as edit LED's. In other words, a loop measure LED 16 lights in correspondence to a loop measure selected by the slider 8 while the user is creating or editing the composition. Thus, in this exemplary embodiment, there is not a separate set of edit LED's to provide such an indication of the loop measure selected for editing. Where an LED acts as both a loop measure LED 16 and an edit LED, the LED may display different properties depending upon the “role” that the LED is assuming. By way of example only, the LED may remain lit while the unit 2 is playing the sample(s) assigned to the loop measure represented by the corresponding column; and the LED may blink when the LED is assuming the role of an edit LED. Other differentiators and combinations will be apparent to those of ordinary skill in the art.

In yet another embodiment, in addition to having loop measure LED's 16 corresponding to each loop measure, the unit 2 has channel LED's 18. In this embodiment, each channel has a channel LED 18 corresponding to each loop measure. Where the user interface comprises a grid, a channel LED 18 will be positioned at each intersection of the horizontal rows (e.g., channels) and vertical columns (e.g., loop measures). Thus, where there are three channels and four loop measures, there will be four loop measure LED's 16 and twelve channel LED's 18. Each channel LED 18 may light in correspondence with a channel and loop measure being edited by the user. Of course, any suitable alternative to a channel LED 18 may be used.

By way of example only, sample selector buttons 6 may be made operable to cycle through the samples stored in the unit 2 for the channel corresponding to the sample selector button 6 when the sample selector button 6 is manipulated, such as while the unit 2 is in “edit” mode by way of example only. The edit LED's, loop measure LED's 16, and/or channel LED's 18 may be configured such that they flash or give some other visual indication when a sample selector button 6 is manipulated. While cycling through the samples stored for each channel by manipulating the sample selector corresponding to the channel, a user may hear the samples with the aid of a communicator, such as, for example, a speaker 4 or other communicator. A user may continue to cycle through the samples stored for the channel corresponding to the sample selector being manipulated by the user until the user decides that a particular sample is preferable for that channel during the selected loop measure. Upon hearing the sample desired for that channel during the selected loop measure, the user may then stop cycling through available samples for the channel (e.g., the user may stop manipulating the corresponding sample selector). The last sample heard by the user for a channel will be deemed selected for that channel for the duration of the selected loop measure. Preferably, each channel will include a selectable sample of silence, such that a user may select a channel to be silent for one or more loop measures. The selection of silence during “stop” mode may be aurally indicated by a soft beep that will not be heard in “play” mode.

In another embodiment, “edit” mode, or a variation of “edit” mode, may coincide with “play” mode, such that a user may select samples while the unit 2 is playing. In other words, a unit 2 may also be made operable to allow a user to select samples while the unit is in “play” mode. For example, if a user wants to change a sample in the first channel during the second loop measure, the user may first move the slider 8 or otherwise manipulate an alternative timing selector to select the second loop measure. The user may then manipulate the first sample selector button 6, or otherwise manipulate an alternative sample selector to cycle through the samples available for the first channel. Each time the sample selector is manipulated in this context, the loop will immediately jump to the beginning of the selected loop measure, the second loop measure for purposes of this example, and the unit 2 will cycle to the next sample available for that channel. While this is happening, the user may also hear the samples previously selected for the other channels at the loop measure being edited. When the user hears the sample preferred for the channel corresponding to the sample selector being manipulated, the user may refrain from further manipulation of the sample selector, and the unit 2 will continue to play, deeming the sample last heard by the user from the particular channel as selected. If the unit 2 has edit LED's, for example, the edit LED corresponding to the loop measure in which the sample is being selected may be made to light during the selection. Other suitable LED configurations will be apparent to those of ordinary skill in the art.

Each unit 2 may have a “random” mode, where samples are selected at random for one or all channels and/or loop measures. A unit 2 may be placed in “random” mode by a particular configuration of the sample selector or selectors and/or timing controller or controllers. By way of example only, for the embodiment shown in FIGS. 1 and 2, a unit 2 could be made to be placed in “random” mode by the user holding all three sample selector buttons 6 down for three seconds. In another embodiment, the unit 2 is placed in “random” mode by the user holding a second and third sample selector button 6 down for three seconds. In yet another embodiment, the unit 2 is placed in “random” mode by the user pressing a second and third sample selector button 6 simultaneously. Alternatively, a unit 2 could include another means for placing the unit 2 in “random” mode, such as, for example, a “random” button, switch, or other suitable alternative. If the unit 2 has edit LED's, the edit LED's may be made to flash to indicate that the unit has completed the random selection of samples for each channel and/or loop measure. Any other suitable indicator(s) may be provided.

In addition, each unit 2 may have a means to adjust the volume of the sound communicated from the unit 2. Such a means could include, by way of example only, a knob, a slider, or as shown in FIGS. 1 and 2, a volume slider 12. In one embodiment, the unit 2 has three preset volume levels, which are selectable with a slider.

Each unit 2 may be pre-programmed (e.g., before purchase by the ultimate consumer) to play music samples of a certain musical style or genre (e.g. rock, classical, etc.). Such samples of the same style may all play at a uniform tempo. In one embodiment, where the tempo is uniform within the range of samples of a given style, the tempo of one style may differ from the tempo of samples in another style. Other suitable stylistic variations will be apparent to those of ordinary skill in the art.

In one embodiment, each unit 2 has a tempo controller for selecting a tempo of the music samples. In the present example, the tempo controller comprises a tempo button 14. In this embodiment, the unit 2 permits selection among four tempo settings (e.g., slow to fast). A user may cycle through the tempo settings by pressing the tempo button 14. Other suitable tempo controllers will be apparent to those of ordinary skill in the art. Those of ordinary skill in the art will appreciate that changing the tempo of a sample may also change the pitch of the sounds in the sample. This may be accounted for by conventional techniques for maintaining pitch while altering tempo.

In another embodiment, the unit 2 permits the user to clear all sample selections by holding a first and second sample selector button 6 down for three seconds. In yet another embodiment, the unit 2 permits the user to clear all sample selections by holding a first and second sample selector button 6 down simultaneously. Of course, a unit 2 may permit a user to clear all sample selections by any other suitable means. The unit 2 may provide an indication, such as a beep or flashing light by way of example only, to indicate that the sample selections have been cleared.

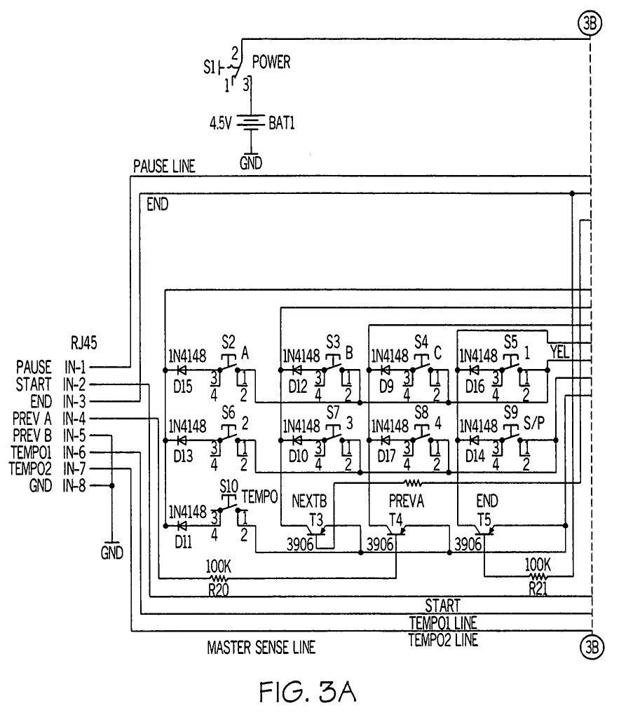

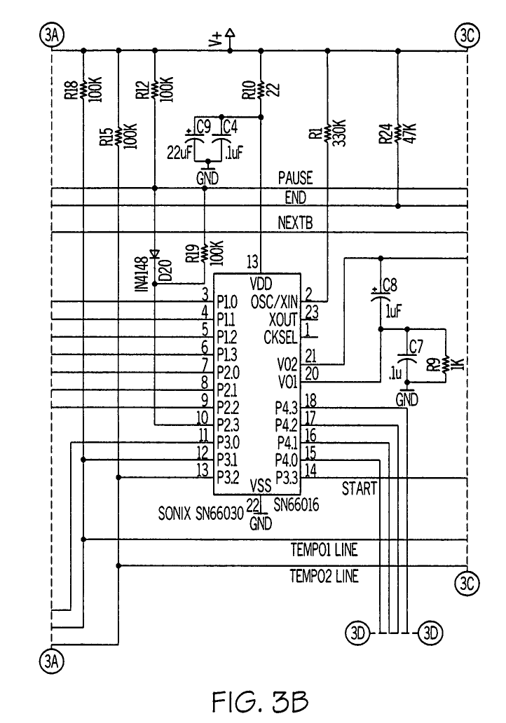

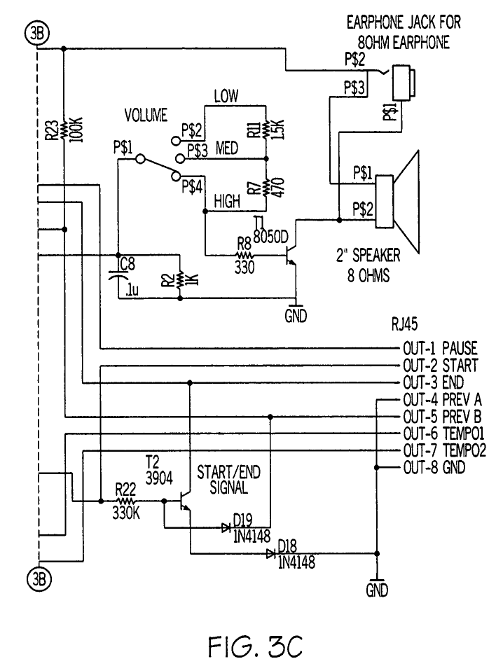

The process of producing audio signals through the communicator or communicators of a unit 2 embodying the present invention may be made to occur in part with a circuit similar to that depicted in FIG. 3. The process includes, but is in no way limited to, the steps of storing one or more samples of sound in a digital form. Preferably, the one or more stored samples of sound will be musical in nature, such that each sample has a rhythm with a tempo. A stored sample or samples may be electronically or otherwise accessible by a user input in electronic or other form. Another step in the process thus includes receiving a user input, wherein the user input represents a selection of a sample. Where a plurality of samples are stored or otherwise accessible and selectable, a user input relating to sample selection may come, in part, via a plurality of switches. By way of example and not limitation, such a plurality of switches may be arranged with a plurality of diodes as depicted in FIG. 3.

The process may further include yet another step or steps of receiving still one or more user input or inputs. Such additional user input or inputs may relate to the selection of loop measures during which one or more selected sample or samples may play. Other suitable user inputs will be apparent to those of ordinary skill in the art.

All or part of the user inputs may be received and processed by, by way of example only, a processor, such as that depicted in FIG. 3, or any alternative process controller. Upon receiving all or part of the user inputs, such a processor or other process controller may be made capable of performing another step in the process of producing audio signals through a unit 2, namely, processing all or part of the received user inputs. Suitable processors include the SN66016, 66030, or 66040 chips by Sonix, Inc., of Springfield, Va. Any other processor or process controller alternative may be used.

The processing of the user input or inputs may be made to result in yet another step of the process of producing audio signals through a unit 2, namely, retrieving one or more of the stored samples of sound, wherein such retrieval is a function of all or part of the user input or inputs.

An additional step to the process of producing audio signals through a unit 2 may be transmitting all or part of the retrieved sound or sounds to a communicator such as speaker 4 or other suitable medium of audio communication. This may include, but is by no means limited to, a headphone jack 5, a USB port, or any other operable means.

Other embodiments and additions to the music-creation device are possible. Some are described below.

Each unit 2 may have a means for introducing the voice of a user into the composition. This may include, a microphone that is built-in to the unit 2 or a microphone jack, by way of example only. Each unit 2 may also have a jack for an earbud or other listening means through which the user could only hear the sample or samples on the channel being modified and/or the sample or samples on the loop measure being modified while the rest of the composition may be heard through another communicator. Thus, the unit 2 may have more than one communicator—including but not limited to one communicator dedicated to communicating edits as they are being made and another communicator dedicated to communicating the entire composition (even during edits).

Each unit 2 may also have one or more dial, button, knob, or other adjusting means to control or alter the tempo and/or pitch(es) of a sample and/or composition. Each unit 2 may also have an LCD screen to display visual indication(s) representing the sample selection(s).

### System of Units

Each unit 2 may have an output 20 or a plurality of outputs 20 and an input 24 or a plurality of inputs 24, such that multiple units 2 may be linked together to form a system of units 2. The one or more outputs 20 may, for example, be in the form of a male connector, such as, a plug by way of example only. The one or more inputs 24 may be, for example, in the form of a female connector, such as a jack, by way of example only.

The units 2 may be made such that each unit 2 is connectable to another unit 2 without additional pieces or parts. Alternatively, the units 2 may be made connectable with a separate cable, etc. Alternatively, the units 2 may be made capable of forming a system without being physically connected. By way of example only, each unit 2 may be made such that a plurality of units 2 may form a wireless system having the same, similar, or different characteristics of the system or systems of units 2 described herein.

In one embodiment, each unit 2 has two inputs 24 and two outputs 20. These inputs 24 and outputs 20 may be provided in the form of a horizontal input 24, a horizontal output 20, a vertical input 24, and a vertical output 20. In one embodiment, the horizontal input 24 is located on the left-hand side of each unit 2, and the horizontal output 20 is located on the right-hand side of each unit 2. The vertical input 24 is located on the upper side of each unit 2, and the vertical output 26 is located on the lower side of each unit 2. These inputs 24 and outputs 20 allow electronic or other communication from one unit 2 to another. One or more of the inputs 24 and/or outputs 20 may further comprise connectors that serve a function of mechanically connecting one unit 2 to another. For example, the vertical inputs 24 and outputs 20 may be integrated into latching mechanisms on the upper and lower side of each unit 2. Of course, the positioning, configuration, and functions served by the inputs 24 and outputs 20 may vary substantially.

In the present example, by connecting a plurality of units 2 horizontally, a user may increase the total length of a loop by adding consecutive loop measures. A plurality of units 2 may be connected horizontally by establishing an electronic or other connection between the horizontal output 20 of one unit 2 and the horizontal input 24 of another unit 2. Where a plurality of units 2 are horizontally connected, the unit 2 in the left-most position may be considered the master unit 40.

In the present example, the user may also increase the number of channels for each loop measure by connecting a plurality of units 2 vertically. A plurality of units 2 may be connected vertically by establishing an electronic or other connection between the vertical output 20 of one unit 2 and the vertical input 24 of another unit 2. Where a plurality of units 2 are vertically connected, the unit 2 in the upper-most position may be considered the master unit 40.

Accordingly, a user may increase the length of a loop and the number of channels by connecting a plurality of units 2 horizontally and a plurality of units vertically. In such a system configuration, the unit 2 in the left-most, upper-most position may be considered the master unit 40, as shown in FIG. 3.

In yet another embodiment, each unit 2 has an output 20 in the form of a RJ-45 style plug 26, which is operatively connected to a cable 28 leading into the main body of the unit 2. In this embodiment, each unit 2 has an input 24 in the form of an RJ-45 style jack 30. Thus, the plug 26 of one unit 2 may be inserted into the jack 30 of another unit 2 to form a system of units 2. Such a system is shown in FIG. 4, where the left-most unit 2 is considered the master unit 40.

Where an output 20 for each unit 2 comprises a plug 26, each unit 2 may further comprise a slot 32 for receiving and storing the plug 26 when the plug 26 is not inserted into the jack 30 of another unit 2.

Other suitable alternatives for inputs 24 and outputs 20, including but not limited to alternative structures and/or functions, will be apparent to those of ordinary skill in the art.

In the present example of a system of units 2, the master unit 40 will send out a timing pulse via its output(s) 20 to units 2 connected to the master unit 40. Where other units 2 are connected in vertical and horizontal directions, the timing pulse may be communicated in both directions (i.e. vertical and horizontal). This timing pulse will ensure that the tempo of the samples comprising the loop, and hence, composition, is kept uniform. The uniformity of tempo may be of particular concern when the samples stored in one unit 2 have a tempo that differs from the tempo of the samples stored in another unit 2. This may occur when there are units 2 having samples of different musical styles. The timing pulse may thus serve to unify the tempos of all samples selectable for a given loop measure in the context of vertically-connected units 2; and to unify the tempos for all loop measures in the context of horizontally-connected units 2.

The timing pulse of the present example will also coordinate the loop measures of vertically-connected units 2 to play in unison with the master unit 40. In other words, the timing pulse may make the loop measures of vertically-connected units 2 begin and end at the same time.

In the horizontal direction of the present example, after the duration of the last loop measure in the master unit 40 has ended, the master unit 40 will send an end of loop measure signal to the next horizontally-connected unit 2. This end of loop measure signal will serve a function of electronically or otherwise commanding the next horizontally-connected unit 2 to begin playing the sample or samples selected for its first loop measure. This next horizontally-connected unit 2 will then play through its loop measures until it reaches the end of its last loop measure. When this next horizontally-connected unit 2 completes its last loop measure, it will send an end of loop measure signal to the next horizontally-connected unit 2, which will play its loop measures. This process will continue until the last loop measure of the last horizontally-connected unit 2 is completed. After this last loop measure is completed, the last horizontally-connected unit 2 will send an end of loop measure signal to the master unit 40. Upon receiving the end of loop measure signal from the last horizontally-connected unit 2, the master unit 40 will begin playing the samples selected for the first loop measure in the master unit 40, starting the whole process again, resulting in the repetition of a loop.

It will be appreciated that other suitable configurations for a system comprising a plurality of units 2 may be used. Alternative system configurations will be apparent to those of ordinary skill in the art.

Having shown and described various embodiments and concepts of the invention, further adaptations of the methods and systems described herein can be accomplished by appropriate modifications by one of ordinary skill in the art without departing from the scope of the invention. While the present invention has been illustrated by description of several embodiments and while the illustrative embodiments have been described in considerable detail, it is not the intention of the applicants to restrict or in any way limit the scope of the appended claims to such detail. Additional advantages and modifications may readily appear to those skilled in the art. Several of such potential alternatives, modifications, and variations have been mentioned, and others will be apparent to those skilled in the art in light of the foregoing teachings. Accordingly, the invention is intended to embrace all such alternatives, modifications and variations as may fall within the spirit and scope of the appended claims and is understood not to be limited to the details of structure and operation shown and described in the specification and drawings.

1. A hand-held music creation device, comprising:
(a) a memory comprising a plurality of samples, each of said samples comprising one or more sounds in digital form, wherein at least one of the samples has a rhythm with a tempo, wherein each sound has a pitch;
(b) one or more sample selectors operable to select a sample from said memory, each sample selector having one or more sample selector outputs, wherein each sample selector output is operable to communicate a selection of a sample;
(c) one or more timing controllers operable to select an interval of time during which one or more selected samples will play, each timing controller having one or more timing controller outputs, wherein each timing controller output is operable to communicate a selection of an interval of time during which one or more selected samples will play;
(d) a process controller operable to process one or more outputs from the one or more sample selectors and one or more outputs from the one or more timing controllers, said process controller having one or more process controller outputs, wherein said one or more process controller outputs communicate one or more processed signals, the one or more processed signals representing samples selected for each selectable interval of time;
(e) a communicator operable to communicate sound as a function of said samples and said one or more processed signals; and
(f) a user interface comprising a grid, said grid comprising one or more sample selectors and one or more timing controllers;
wherein the sum of the selectable intervals of time comprises a loop, wherein said loop repeats indefinitely.

2. The hand-held music creation device of claim 1, further comprising a controller operable to alter the tempo of said samples.

3. The hand-held music creation device of claim 1, further comprising a controller operable to alter the pitch of one or more sound in a sample.

4. The hand-held music creation device of claim 1, further comprising a loop time display operable to display the interval of time at which the loop is playing.

5. The hand-held music creation device of claim 1, further comprising a sample selection display operable to display a sample selection.

6. The hand-held music creation device of claim 1, further comprising a receiver operable to receive a voice of a user.

7. The electronic hand-held music creation device of claim 1, further comprising:
(a) an output operable to send an output signal to another electronic device; and
(b) an input operable to receive an output signal of another electronic device.

8. A system of devices, comprising:
(a) a system comprising a plurality of the devices of claim 7;
(b) at least one connector, wherein each connector is operable to connect one of the devices to another device;
(c) at least one of:
(i) a sample aggregator operable to aggregate the samples in the devices into a range of system samples, or
(ii) a loop length aggregator operable to aggregate the length of the loops produced by the devices into a single loop of the system;
and
(d) a tempo synchronizer operable to synchronize the tempo of the samples from the devices that form the system.

9. A method of generating audio signals, comprising the steps of:
(a) receiving one or more user inputs, wherein said one or more user inputs relate to one or more samples within a plurality of samples stored in digital form;
(b) processing the one or more user inputs;
(c) retrieving one or more of the samples within the plurality of samples stored in digital form as a function of the one or more samples within the plurality of samples stored in digital form and the processed one or more user inputs; and
(d) communicating the one or more retrieved samples in accordance with the retrieval.
